(19) United States
(12) Patent Application Publication
(10) Pub. No.: US 2025/0335041 A1
(43) Pub. Date: Oct. 30, 2025

(54) LIGHT-EMITTING STRUCTURE AND PRESS KEY

(71) Applicants: BRIGHTEK OPTOELECTRONIC CO., LTD (SHENZHEN), Shenzhen (CN); BRIGHTEK OPTOELECTRONIC CO., LTD, Taoyuan City (CN)

(72) Inventors: Ching-Liang LEE, Shenzhen (CN); Chien-Chung HUANG, Shenzhen (CN)

(21) Appl. No.: 18/941,730

(22) Filed: Nov. 8, 2024

(30) Foreign Application Priority Data
Apr. 30, 2024 (CN) 202410540624.6

(51) Int. Cl. G06F 3/02; F21V 7/00; F21V 9/00; F21Y 115/10; H01L 33/48; H01L 33/58

(52) U.S. Cl. CPC G06F 3/0202; F21V 7/0008; F21V 9/00; H10H 20/8506; H10H 20/855; F21Y 2115/10

(57) ABSTRACT

A light-emitting structure including: a circuit substrate; a light-emitting element, arranged on the circuit substrate; a light-transmitting body, arranged on the circuit substrate and packaging an outside of the light-emitting element and having a light-exiting surface facing away from the circuit substrate; and a light-shielding body, arranged on the circuit substrate and packaging an outside of the light-transmitting body and having a light-exiting part. The light-exiting part has two first light-exiting holes for emitting light. The two first light-exiting holes are arranged at intervals; or, the two first light-exiting holes are partially overlapped, centers of the two first light-exiting holes are arranged at intervals along a first direction, a maximum dimension of an overlapping portion of the two first light-exiting holes in a second direction, which is perpendicular to the second direction, is smaller than a maximum dimension of one of the two first light-exiting holes in the second direction.

### CROSS-REFERENCE TO RELATED APPLICATIONS

Pursuant to 35 U.S.C. § 119 and the Paris Convention, this application claims the benefit of Chinese Patent Application No. 202410540624.6 filed Apr. 30, 2024, the contents of which are incorporated herein by reference.

### BACKGROUND

### Technical Field

The present application relates to the technical field of press key light-emitting technology, more particularly to a light-emitting structure and a press key.

### Description of Related Art

With the development of technology, electronic devices have developed rapidly. In order to facilitate the use of electronic devices, a typical electronic device is usually equipped with a press key, and a light-emitting structure is provided inside a keycap of the press key, and a light-emitting hole is provided at a position corresponding to the keycap and the light-emitting structure. The light emitted by the light-emitting structure is transmitted through the light-emitting hole, and the light emitted through the light-emitting hole indicates whether the function corresponding to the press key is turned on.

However, with the diverse needs of the press key, when the light-emitting hole is constructed as a strip-shaped hole, the light emitted by the traditional light-emitting structure passes through the light-emitting hole, and the light transmitted through the light-emitting hole has a higher intensity distribution at the center position and low intensity distributions at two ends, which is prone to occur a halo phenomenon of the strong bright spot in the center, that is, the “starburst” phenomenon, which causes users to have poor visual experience and color difference problems.

### SUMMARY

It is an objective of the present application to provide a light-emitting structure and a press key, so as to solve the problems including but not limited to the “starburst” phenomenon that easily occurs in the press key in the related art.

The following technical solutions are adopted by embodiments of the present application:

In a first aspect, a light-emitting structure is provided. The light-emitting structure comprises: a circuit substrate; a light-emitting element, arranged on the circuit substrate; a light-transmitting body, arranged on the circuit substrate and packaging an outside of the light-emitting element, the light-transmitting body having a light-exiting surface facing away from the circuit substrate; and a light-shielding body, arranged on the circuit substrate and packaging an outside of the light-transmitting body, the light-shielding body having a light-exiting part arranged on the light-exiting surface. The light-exiting part has two first light-exiting holes for emitting light. The two first light-exiting holes are arranged at intervals; or alternatively, the two first light-exiting holes are partially overlapped, centers of the two first light-exiting holes are arranged at intervals along a first direction, a maximum dimension of an overlapping portion of the two first light-exiting holes in a second direction is smaller than a maximum dimension of one of the two first light-exiting holes in the second direction, and the first direction is perpendicular to the second direction.

In an optional embodiment of the present application, orthographic projections of centers of light inlets of the two first light-exiting holes on the circuit substrate are respectively arranged on opposite sides of an orthographic projection of a center of the light-emitting element on the circuit substrate.

In an optional embodiment of the present application, the orthographic projections of the centers of the light inlets of the two first light-exiting holes on the circuit substrate are collinear with the orthographic projection of the center of the light-emitting element on the circuit substrate.

In an optional embodiment of the present application, the two first light-exiting holes are respectively circular holes.

In an optional embodiment of the present application, the two first light-exiting holes are arranged at intervals, and the light-exiting part has a second light-exiting hole. The second light-exiting hole is arranged between the two first light-exiting holes. The maximum dimension of the first light-exiting hole in the second direction is greater than a maximum dimension of the second light-exiting hole in the second direction.

In an optional embodiment of the present application, the second light-exiting hole is communicated with the two first light-exiting holes. Orthographic projections of centers of the light inlets of the two first light-exiting holes on the circuit substrate, an orthographic projection of a center of a light inlet of the second light-exiting hole on the circuit substrate, and an orthographic projection of a center of the light-emitting element on the circuit substrate are arranged in a collinear manner.

In an optional embodiment of the present application, the two first light-exiting holes are respectively circular holes, and the second light-exiting hole is a strip-shaped hole.

In an optional embodiment of the present application, orthographic projections of light inlets of the two first light-exiting holes on the circuit substrate are respectively arranged on opposite sides of an orthographic projection of the light-emitting element on the circuit substrate. The orthographic projections of the light inlets of the two first light-exiting holes on the circuit substrate do not overlap with the orthographic projection of the light-emitting element on the circuit substrate.

In an optional embodiment of the present application, the light-shielding body comprises a light-absorbing sub-body and a light-reflecting sub-body, the light-reflecting sub-body packages the outside of the light-transmitting body, the light-absorbing sub-body packages the outside of the light-reflecting sub-body, and a lateral side of the light-shielding body is flush with a lateral side of the circuit substrate.

In a second aspect, a press key is provided. The press key comprises: a keycap and the light-emitting structure as described in the above. The keycap is provided with a light-emitting hole, the light-emitting hole is a strip-shaped hole, the light-emitting structure is arranged inside the keycap, the light-exiting part is arranged opposite to the light-emitting hole, and the two first light-exiting holes are arranged along a length direction of the strip-shaped hole.

The above one or more technical solutions in the light-emitting structure and the press key provided in the present application have at least one of the following advantages: the light-emitting structure can elongate the light-emitting area of the light-emitting structure, so that the light emission of the light-emitting hole of the related technology is more dispersed, the light-emitting uniformity of the light-emitting hole can be better improved and the “starburst” phenomenon can be improved, thereby making the user have a good visual experience and reducing the color difference. In addition, when the two first light-exiting holes are partially overlapped and the maximum dimension of the overlapping portion of the first light-exiting holes in the second direction is smaller than the maximum dimension of the first light-exiting hole in the second direction, the width of the light-exiting area of the overlapping portion of the two first light-exiting holes can be small, and the width of the light-exiting area at the two ends can be large, which can weaken the light-emitting intensity of the center of the light-emitting hole, and therefore, the light-emitting uniformity of the light-emitting hole can be improved and the “starburst” phenomenon can be improved, thereby making the user have a good visual experience and reducing the color difference.

The above description is only an overview of the technical solutions of the present application. In order to more clearly understand the technical means of the present application and to implement the inventions according to the content of the specification, and in order to make the above and other purposes, features and advantages of the present application more obvious and easy to understand, the specific implementation method of the present application is specifically explained hereinbelow.

### DESCRIPTION OF THE DRAWINGS

In order to more clearly illustrate the technical solutions in the embodiments of the present application, the drawings that need to be used in the description of the embodiments or the prior art will be briefly described hereinbelow. Obviously, the accompanying drawings in the following description are only some embodiments of the present application. For those skilled in the art, other drawings can be obtained based on these drawings without creative work.

FIG. 1 is a structural schematic diagram of a press key provided in some embodiments of the present application.

FIG. 2 is a structural schematic diagram of a light-emitting structure shown in FIG. 1.

FIG. 3 is a cross-sectional view taken from line A-A in FIG. 2.

FIG. 4 is an exploded schematic diagram of the light-emitting structure shown in FIG. 3.

FIG. 5 is a structural schematic diagram of the light-emitting structure provided in other embodiments of the present application.

FIG. 6 is a structural schematic diagram of the light-emitting structure provided in some other embodiments of the present application.

FIG. 7 is a cross-sectional view of the light-emitting structure provided in some other embodiments of the present application taken from line A-A in FIG. 2.

FIG. 8 is a cross-sectional view of the light-emitting structure provided in some other embodiments of the present application taken from line A-A in FIG. 2.

In the drawings, the following reference numerals are adopted:

100, press key; 10, light-emitting structure; 11, circuit substrate; 12, light-emitting element; 13, light-transmitting body; 131, light-exiting surface; 14, light-shielding body; 141, light-exiting part; 142, side wall; 143, light-absorbing sub-body; 144, light-reflecting sub-body; 145, first light-exiting hole; 1451, light inlet; 146, second light-exiting hole; 20, keycap; and 21, light-emitting hole.

### DETAILED DESCRIPTION OF THE EMBODIMENTS

In order to make the purposes, technical solutions, and advantages of the present application clearer and more understandable, the present application will be further described in detail hereinafter with reference to the accompanying drawings and embodiments. It should be understood that the embodiments described herein are only intended to illustrate but not to limit the present application.

In the description of the embodiments of the present application, unless otherwise clearly specified and limited, when an element is described as “fixed” or “arranged” on/at another element, it means that the element can be directly or indirectly fixed or arranged on/at another element. When an element is described as “connected” to/with another element, it means that the element can be directly or indirectly connected to/with another element.

The embodiments of the present application provide a light-emitting structure, which can improve the light-emitting uniformity of the light-emitting hole of the keycap and improve the “starburst” phenomenon, so that the user has a good visual experience and reduces the color difference.

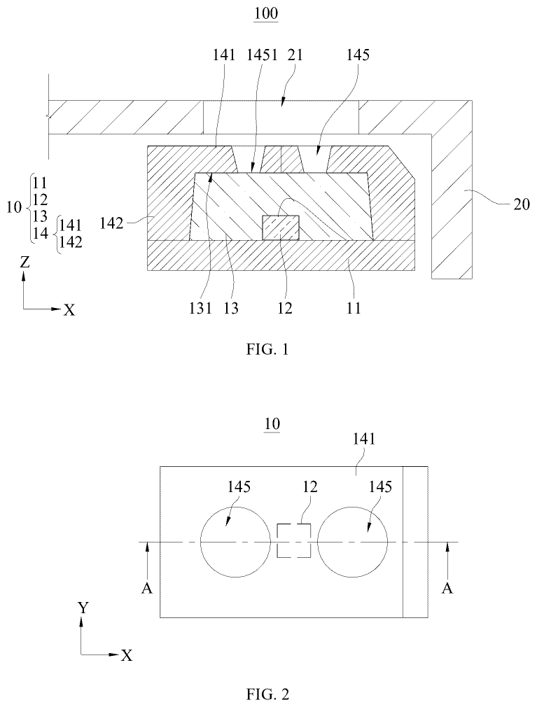

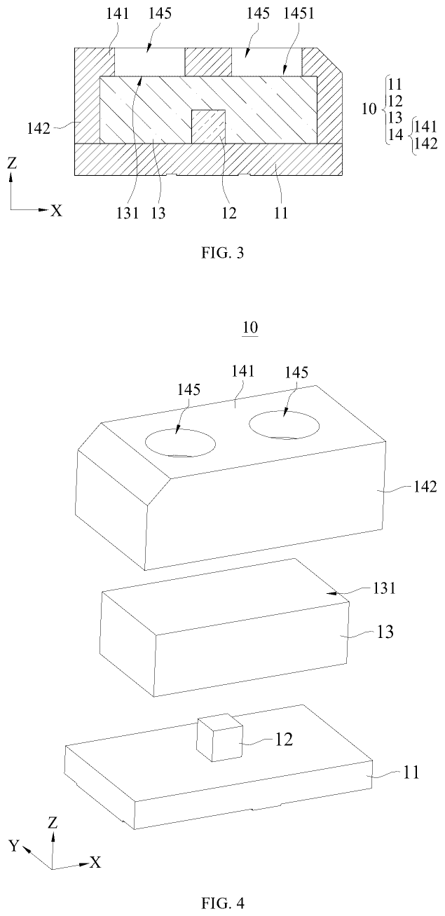

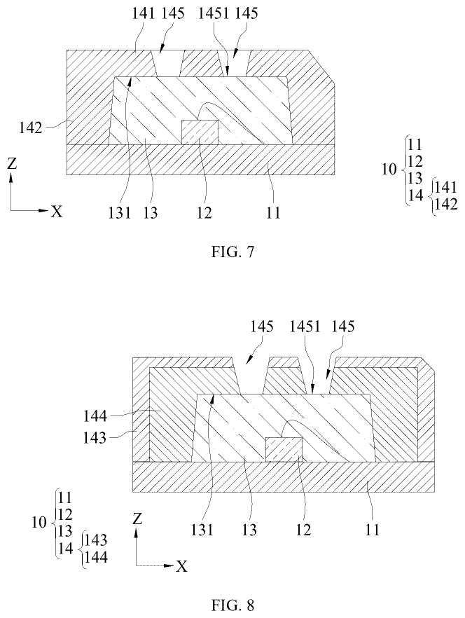

The light-emitting structure 10 of the embodiment of the present application is described below in conjunction with FIGS. 1-8.

Referring to FIGS. 1-8, embodiments of the present application provide a light-emitting structure 10, which includes: a circuit substrate 11, a light-emitting element 12, a light-transmitting body 13, and a light-shielding body 14. The light-emitting element 12 is arranged on the circuit substrate 11. The light-transmitting body 13 is arranged on the circuit substrate 11 and packages an outside of the light-emitting element 12, and the light-transmitting body 13 has a light-exiting surface 131 facing away from the circuit substrate 11. The light-shielding body 14 is arranged on the circuit substrate 11 and packages an outside of the light-transmitting body 13, and the light-shielding body 14 has a light-exiting part 141 arranged on the light-exiting surface 131. The light-exiting part 141 has two first light-exiting holes 145 for emitting light. The two first light-exiting holes 145 are arranged at intervals; or alternatively, the two first light-exiting holes 145 are partially overlapped, centers of the two first light-exiting holes 145 are arranged at intervals along a first direction, a maximum dimension L1 of an overlapping portion of the two first light-exiting holes 145 in a second direction is smaller than maximum dimension L2 of the first light-exiting hole 145 in the second direction, and the first direction is perpendicular to the second direction.

The shapes and dimensions of the two first light-exiting holes 145 may be the same to achieve uniform light emission. It can be understood that in other examples, the shapes and dimensions of the two first light-exiting holes 145 may be different, for example, the apertures of the two first light-exiting holes 145 are different.

The circuit substrate 11 may refer to a component for mounting the light-emitting element 12. The circuit substrate 11 may support and electrically connect the light-emitting element 12. The circuit substrate 11 may be a hard circuit board or a flexible circuit board.

The light-emitting element 12 may refer to a component that can emit light, such as an light-emitting diode (LED) lamp bead. The light-emitting element 12 may be fixed to the surface of the circuit substrate 11 by a solid state welding process to facilitate the connection between the light-emitting element 12 and the circuit substrate 11.

The light-transmitting body 13 may refer to a light-transmitting component wrapped around the light-emitting element 12. The light-transmitting body 13 may be packaged outside of the light-emitting element 12 by injection molding or the like. The light-transmitting body 13 allows the light emitted by the light-emitting element 12 to pass through. In addition, the light-transmitting body 13 may also protect the light-emitting element 12. The light-transmitting body 13 may refer to a transparent colloid (for example, a transparent epoxy colloid) or a fluorescent colloid.

The surface of the light-transmitting body 13 facing away from the circuit substrate 11 is the light-exiting surface 131. The light emitted by the light-emitting element 12 is emitted through the light-exiting surface 131 and then emitted through the first light-exiting holes 145, thereby realizing the light-emitting structure 10.

The light-shielding body 14 may refer to a light-shielding component coated on the light-transmitting body 13. The light-shielding body 14 may absorb the light emitted from the light-transmitting body 13 or block the light emitted by the light-transmitting body 13 from being emitted outwards. The portion of the light-shielding body 14 covering the light-exiting surface 131 is the light-exiting part 141. The light-exiting part 141 is provided with first light-exiting holes 145. The first light-exiting holes 145 penetrate the light-exiting part 141. The light emitted by the light-emitting element 12 passes through the light-transmitting body 13, then passes through the light-exiting surface 131, and finally passes through the first light-exiting holes 145, thereby realizing the light emission of the light-emitting structure 10. However, the light emitted by the light-transmitting body 13 at positions other than the position corresponding to the first light-exiting holes 145 may be absorbed or blocked by the light-shielding body 14 to reduce light leakage. The light-shielding body 14 may be, for example, a black colloid to achieve a better light-absorbing effect. The light-shielding body 14 may be encapsulated outside the light-transmitting body 13 by injection molding or the like. The light-shielding body 14 can be a single-layer structure or a multi-layer structure.

The light-exiting part 141 is provided with two first light-exiting holes 145 for light emission. The first light-exiting holes 145 can adopt various shapes, such as: circular, rectangular, and the like. Preferably, the shapes of the first light-exiting holes 145 are circular.

Referring to FIG. 2, the two first light-exiting holes 145 are arranged at intervals, which may mean that there is a certain spacing between the two first light-exiting holes 145. When the light-emitting structure 10 is used in conjunction with the strip-shaped light-emitting hole 21, the two first light-exiting holes 145 can be arranged in a length direction of the light-emitting hole 21, so that there are two light source points in the length direction of the light-emitting hole 21, and the light-emitting area of the light-emitting structure 10 in the length direction of the light-emitting hole 21 can be elongated, so that the light emission of the light-emitting hole 21 is more dispersed, and the light-emitting uniformity of the light-emitting hole 21 can be better improved and the “starburst” phenomenon can be improved, thereby making the user have a good visual experience and reducing the color difference.

As shown in FIG. 5, the two first light-exiting holes 145 are only partially overlapped, that is, the two first light-exiting holes 145 are connected to each other, and the centers of the two first light-exiting holes 145 are arranged at intervals along the first direction, and the maximum dimension L1 of the overlapping portion of the two first light-exiting holes 145 in the second direction is smaller than the maximum dimension L2 of the first light-exiting hole 145 in the second direction, and the first direction is perpendicular to the second direction, so that the two first light-exiting holes 145 have partial areas that overlap and partial areas that are not overlap. The overlapping area may refer to the area enclosed by two dotted lines.

When the light-emitting structure 10 is used in conjunction with the strip-shaped light-emitting hole 21, the length direction of the light-emitting hole 21 is parallel to the first direction, the two first light-exiting holes 145 are partially overlapped, and the centers of the two first light-exiting holes 145 are arranged at intervals along the first direction, and the maximum dimension L1 of the overlapping portion of the two first light-exiting holes 145 in the second direction is smaller than the maximum dimension L2 of the first light-exiting hole 145 in the second direction, and the first direction is perpendicular to the second direction. On the one hand, the light-emitting area of the light-emitting structure 10 in the length direction of the light-emitting hole 21 can be elongated, so that the light emission of the light-emitting hole 21 is more dispersed; on the other hand, the width of the light-exiting area of the overlapping portion of the two first light-exiting holes 145 can be small, and the width of the light-exiting area at the two ends can be large, which can weaken the light-emitting intensity of the center of the light-emitting hole 21, and therefore, the light-emitting uniformity of the light-emitting hole 21 can be improved and the “starburst” phenomenon can be improved, thereby making the user have a good visual experience and reducing the color difference.

The centers of the first light-exiting holes 145 may refer to the geometric centers of the first light-exiting holes 145; for example, the first light-exiting holes 145 are respectively circular holes, and the geometric centers of the circular holes are the centers of the first light-exiting holes 145, respectively. The two circular holes partially overlap, and the overlapping portion does not exceed the center of the circular hole.

Referring to FIGS. 1-3 and 7-8, the circular hole may refer to a hole structure whose cross section is circular, and the aperture of the circular hole along the axial direction may be constant, or may gradually increase or decrease.

The first direction may refer to the length direction of the light-emitting structure 10 (referring to the X direction), and the second direction may refer to the width direction of the light-emitting structure 10 (referring to the Y direction).

In some embodiments, the light-shielding body 14 further includes a side wall 142, which is connected to a periphery of the light-exiting part 141, and the side wall 142 is arranged around the light-transmitting body 13 to block the light emitted from the peripheral wall of the light-transmitting body 13, thereby reducing the light leakage from the side of the light-emitting structure 10, and improving the light-emitting uniformity of the light-emitting hole 21.

In some other embodiments of the present application, as shown in FIG. 2, orthographic projections of centers of light inlets 1451 of the two first light-exiting holes 145 on the circuit substrate 11 are respectively arranged on opposite sides of an orthographic projection of a center of the light-emitting element 12 on the circuit substrate 11, so as to ensure a symmetrical arrangement and achieve the effect of light-emitting uniformity.

It can be understood that, from the direction of the light-exiting part 141 toward the circuit substrate 11 (defined as the third direction, the third direction can refer to the height direction of the light-emitting structure 10 (refer to the Z direction)), the centers of the light inlets 1451 of the two first light-exiting holes 145 are arranged on opposite sides of the center of the light-emitting element 12. The openings of the first light-exiting holes 145 formed on the surface of the light-exiting part 141 covering the light-exiting surface 131 are the light inlets 1451 of the first light-exiting holes 145. The light emitted from the light-exiting surface 131 enters the first light-exiting holes 145 via the light inlets 1451, and finally exits the first light-exiting holes 145, so that the light-emitting structure 10 emits light.

The light inlets 1451 of the two first light-exiting holes 145 are arranged on opposite sides of the center of the light-emitting element 12, which will effectively prevent the light emitted by the light-emitting element 12 from directly exiting the first light-exiting hole 145, so that the light intensity entering the two first light-exiting holes 145 will not be too high, which can improve the light-emitting uniformity of the light-emitting hole 21 and improve the “starburst” phenomenon.

In other embodiments of the present application, as shown in FIG. 2, the orthographic projections of the centers of the light inlets 1451 of the two first light-exiting holes 145 on the circuit substrate 11 are collinear with the orthographic projection of the center of the light-emitting element 12 on the circuit substrate 11, so as to effectively elongate the light-exiting area.

It can be understood that, from the direction of the light-exiting part 141 toward the circuit substrate 11, the centers of the light inlets 1451 of the two first light-exiting holes 145 and the center of the light-emitting element 12 are arranged on the same straight line; the center of the light-emitting element 12 can be arranged in the middle of the centers of the light inlets 1451 of the two first light-exiting holes 145, so that the distances from the light-emitting element 12 to the two first light-exiting holes 145 are the same or not much different, so that the light entering the two first light-exiting holes 145 is the same or not much different, which can improve the light-emitting uniformity of the light-emitting hole 21 and improve the “starburst” phenomenon.

In other embodiments of the present application, as shown in FIG. 2, the two first light-exiting holes 145 are respectively circular holes. By adopting the technical solutions of these embodiments, the shapes of the first light-exiting holes 145 are simple and the exiting light is uniform, which can achieve more efficient processing and manufacturing.

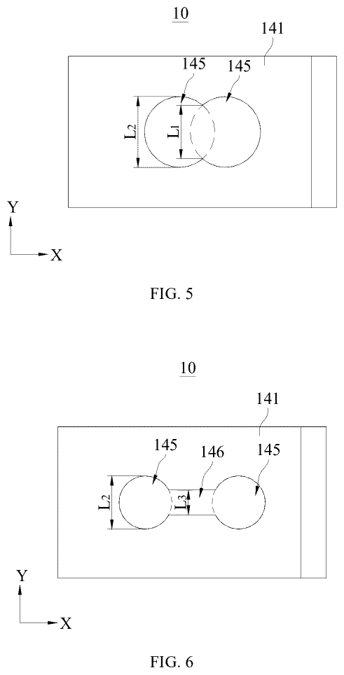

In some other embodiments of the present application, as shown in FIG. 6, the two first light-exiting holes 145 are arranged at intervals, and the light-exiting part 141 has a second light-exiting hole 146, which is arranged between the two first light-exiting holes 145, and the maximum dimension L2 of the first light-exiting hole 145 in the second direction is greater than a maximum dimension L3 of the second light-exiting hole 146 in the second direction. The second light-exiting hole 146 can communicated with one of the first light-exiting holes 145, or can be communicated with both the two first light-exiting holes 145, or can be not communicated with both the two first light-exiting holes 145.

The second light-exiting hole 146 penetrates through the light-exiting part 141, and the opening formed by the second light-exiting hole 146 on the surface of the light-exiting part 141 covering the light-exiting surface 131 is the light inlet of the second light-exiting hole 146. The light emitted from the light-exiting surface 131 enters the second light-exiting hole 146 from the light inlet of the second light-exiting hole 146, and is finally emitted through the second light-exiting hole 146, so that the light-emitting structure 10 emits light.

By adopting the technical solution of this embodiment, on the one hand, the second light-exiting hole 146 can increase the light-exiting area of the light-emitting structure 10 in the length direction of the light-emitting hole 21. In addition, the maximum dimension L2 of the first light-exiting hole 145 in the second direction is greater than the maximum dimension L3 of the second light-exiting hole 146 in the second direction, so that the width of the light-exiting area of the light-exiting part 141 in the middle position is small, and the width of the light-exiting area at both ends is large, so that the light intensity of the center of the light-emitting hole 21 can be weakened, thereby improving the light-emitting uniformity of the light-emitting hole 21.

In other embodiments of the present application, referring to FIG. 6, the second light-exiting hole 146 is communicated with the two first light-exiting holes 145. The orthographic projections of the centers of the light inlets 1451 of the two first light-exiting holes 145 on the circuit substrate 11, an orthographic projection of a center of a light inlet of the second light-exiting hole 146 on the circuit substrate 11, and an orthographic projection of a center of the light-emitting element 12 on the circuit substrate 11 are arranged in a collinear manner. Such implementation manner allows the centers of the light inlets 1451 of the two first light-exiting holes 145, the center of the light inlet of the second light-exiting hole 146, and the center of the light-emitting element 12 to be arranged along the length direction of the light exit hole 21, so that the light-emitting uniformity of the light exit hole 21 can be improved.

It can be understood that the two ends of the second light-exiting hole 146 can be connected to the two first light-exiting holes 145, and the light-exiting part 141 forms a whole area of light emission. From the direction of the light-exiting part 141 toward the circuit substrate 11, the centers of the light inlets 1451 of the two first light-exiting holes 145, the center of the light inlet of the second light-exiting hole 146, and the center of the light-emitting element 12 are arranged on the same straight line, the center of the light inlet of the second light-exiting hole 146 can be arranged in the middle of the centers of the light inlets 1451 of the two first light-exiting holes 145, and the center of the light inlet of the second light-exiting hole 146 can coincide with the center of the light-emitting element 12. This implementation manner can improve the light-emitting uniformity of the light exit hole 21 and improve the “starburst” phenomenon.

In other embodiments of the present application, as shown in FIG. 6, the two first light-exiting holes 145 are respectively circular holes, and the second light-exiting hole 146 is a strip-shaped hole. By adopting the technical solutions of these embodiments, the shapes of the first light-exiting holes 145 and the second light-exiting hole 146 are simple and the light emission is uniform, which can achieve more efficient processing and manufacturing.

In other embodiments of the present application, as shown in FIG. 2, the orthographic projections of the light inlets 1451 of the two first light-exiting holes 145 on the circuit substrate 11 are respectively arranged on opposite sides of an orthographic projection of the light-emitting element 12 on the circuit substrate 11. The orthographic projections of the light inlets of the two first light-exiting holes 145 on the circuit substrate 11 do not overlap with the orthographic projection of the light-emitting element 12 on the circuit substrate 11.

It can be understood that, viewed from the third direction, the two first light-exiting holes 145 are arranged on opposite sides of the light-emitting element 12, and the two first light-exiting holes 145 can be completely misaligned with the light-emitting element 12.

For example, when the light-exiting part 141 only has two first light-exiting holes 145 arranged at intervals, the portion of the light-exiting part 141 between the two first light-exiting holes 145 can shield the light-emitting element 12 and can shield the strong light-emitting point of the light-emitting element 12, that is, the light emitted by the first light-exiting holes 145 is not easy to have a strong bright light point, and the light-emitting uniformity of the first light-exiting holes 145 is good. In addition, with the arrangement of the two first light-exiting holes 145, the light-emitting structure 10 has two light-emitting positions, and the two light-emitting positions are spaced along the length direction of the light-emitting hole 21. The light emission of the light-emitting hole 21 is more dispersed, so that the light-emitting uniformity of the light-emitting hole 21 can be better improved and the “starburst” phenomenon can be improved, thereby making the user have a good visual experience and reduce the color difference.

For example, when the light-exiting part 141 has a second light-exiting hole 146 and two first light-exiting holes 145 arranged at intervals, the light-emitting element 12 can be arranged opposite to the second light-exiting hole 146, and the light emitted from the center of the light-emitting element 12 can be directly emitted through the second light-exiting hole 146, while the second light-exiting hole 146 is narrow and the light output is limited, and the maximum dimension L2 of one of the two first light-exiting holes 145 is large, and the light output is large, so that the light-emitting uniformity of the light-emitting hole 21 can be improved, and the “starburst” phenomenon can be improved.

In some embodiments of the present application, as shown in FIG. 8, the light-shielding body 14 comprises a light-absorbing sub-body 143 and a light-reflecting sub-body 144, the light-reflecting sub-body 144 packages the outside of the light-transmitting body 13, the light-absorbing sub-body 143 packages the outside of the light-reflecting sub-body 144, and a lateral side of the light-shielding body 14 is flush with a lateral side of the circuit substrate 11.

The light-shielding body 14 is a double-layer structure, an inner layer is the light-reflecting sub-body 144, and an outer layer is the light-absorbing sub-body 143. The light-reflecting sub-body 144 packages the outside of the light-transmitting body 13, and the light-absorbing sub-body 143 packages the outside of the light-reflecting sub-body 144. The light-reflecting sub-body 144 is mainly used to reflect light, and the light-absorbing sub-body 143 is mainly used to absorb light to reduce light leakage from the light-emitting structure 10. The light-absorbing sub-body 143 can be a black glue colloid, and the light-reflecting sub-body 144 can be a white colloid, such as a white glue like a white epoxy glue. By adopting the technical solution of this embodiment, a part of the light emitted by the light-emitting element 12 can be reflected by the light-reflecting sub-body 144 and then emitted through the first light-exiting hole 145, so that the emitted light of the first light-exiting hole 145 can be increased, and the light-emitting brightness of the light-emitting structure 10 can be improved, so that the light-emitting hole 21 has a better light-emitting effect, and is easy to process and manufacture.

The lateral side of the light-shielding body 14 is flush with the lateral side of the circuit substrate 11, which not only improves the efficiency of the manufacturing process, but also makes the overall volume of the light-emitting structure 10 flat and small, thus being conducive to the subsequent application in the small-sized keycap 20.

Since the light-shielding body 14 absorbs the emitted light of the light-emitting element 12 while preventing the light leakage from the side, and the positions of the first light-exiting holes 145 are misaligned with the light-emitting center of the light-emitting element 12, which may cause the light-emitting brightness of the light-emitting structure 10 to be difficult to improve; in embodiments of the present application, the light-emitting structure 10 is obtained by three injection molding processes, and the light-emitting structure 10 having the light-reflecting sub-body 144 arranged at the inner side and the light-absorbing sub-body 143 arranged on the outer side is obtained, thereby improving the light brightness and reducing light leakage, and meeting the light-emitting uniformity requirements of the light-emitting hole 21.

Most of the light emitted by the light-emitting element 12 will be reflected by the inner wall surface of the light-reflecting sub-body 144, thereby increasing the brightness of the light emitted by the first light-exiting holes 145; however, due to the limited characteristics of the material itself, the light-reflecting sub-body 144 can reflect most of the light, and some of the light will pass through the light-reflecting sub-body 144, resulting in light leakage, which cannot meet the requirements of the light-emitting uniformity of the light-emitting hole 21. Therefore, it is also necessary to injection mold the light-absorbing glue (such as black glue, etc.) on the outer side of the light-reflecting sub-body 144 to obtain the light-absorbing sub-body 143. The light-reflecting sub-body 144 and the light-absorbing sub-body 143 together form the light-shielding body 14; the light-absorbing sub-body 143 covers the peripheral side wall of the light-reflecting sub-body 144, and the light-absorbing sub-body 143 can efficiently absorb light, so that the light-emitting structure 10 can only emit light through the first light-exiting holes 145 of the light-shielding body 14, thereby reducing light leakage and meeting the requirements of the light-emitting uniformity of the light-emitting hole 21.

In some embodiments of the present application, referring to FIG. 1, a press key 100 is provided, which comprises a keycap 20 and the light-emitting structure 10 as described in the above embodiments. The keycap 20 is provided with a light-emitting hole 21, which is a strip-shaped hole, the light-emitting structure 10 is arranged inside the keycap 20, the light-exiting part 141 is arranged opposite to the light-emitting hole 21, and the two first light-exiting holes 145 are arranged along a length direction of the strip-shaped hole.

In the third direction, the light-emitting hole 21, the light-exiting part 141, and the light-emitting element 12 are arranged in sequence, and the two first light-exiting holes 145 are arranged along the length direction of the strip-shaped hole, and the light-emitting hole 21 is strip-shaped. After the light emitted by the light-emitting element 12 passes through the light-transmitting body 13, the light then enters the first light-exiting holes 145, and then the light passes through the first light-exiting holes 145 and enters the light-emitting hole 21, and finally exits from the light-emitting hole 21, so that the light-emitting hole 21 of the press key 100 emits light.

The press key 100 of the embodiments of the present application adopts the above-mentioned light-emitting structure 10, so that the light emission of the strip-shaped light-emitting hole 21 is more dispersed, the light-emitting uniformity of the light-emitting hole 21 can be better improved and the “starburst” phenomenon can be improved, thereby making the user have a good visual experience and reduce the color difference.

The above description of embodiments tends to emphasize the differences between the embodiments, and the same or similar parts can be referenced to each other. For the simplicity, such same or similar parts will not be repeated herein.

Finally, it should be noted that the above embodiments are only used to illustrate the technical solutions of the present application, rather than to limit them; although the present application has been described in detail with reference to the aforementioned embodiments, those skilled in the art should understand that they can still modify the technical solutions described in the aforementioned embodiments, or replace some or all of the technical features therein by equivalents; and these modifications or replacements do not make the essence of the corresponding technical solutions deviate from the scope of the technical solutions of the embodiments of the present application, and should be included in the scope of the claims and specification of the present application. In particular, as long as there is no structural conflict, the various technical features mentioned in the various embodiments can be combined in any way. The present application is not limited to the specific embodiments disclosed herein, but includes all technical solutions that fall within the scope of the claims.

What is claimed is:

1. A light-emitting structure, comprising:
a circuit substrate;
a light-emitting element, arranged on the circuit substrate;
a light-transmitting body, arranged on the circuit substrate and packaging an outside of the light-emitting element, the light-transmitting body having a light-exiting surface facing away from the circuit substrate; and
a light-shielding body, arranged on the circuit substrate and packaging an outside of the light-transmitting body, the light-shielding body having a light-exiting part arranged on the light-exiting surface, the light-exiting part having two first light-exiting holes for emitting light;
wherein the two first light-exiting holes are arranged at intervals; or alternatively, wherein the two first light-exiting holes are partially overlapped, centers of the two first light-exiting holes are arranged at intervals along a first direction, a maximum dimension of an overlapping portion of the two first light-exiting holes in a second direction is smaller than a maximum dimension of one of the two first light-exiting holes in the second direction, and the first direction is perpendicular to the second direction.

2. The light-emitting structure according to claim 1, wherein orthographic projections of centers of light inlets of the two first light-exiting holes on the circuit substrate are respectively arranged on opposite sides of an orthographic projection of a center of the light-emitting element on the circuit substrate.

3. The light-emitting structure according to claim 2, wherein the orthographic projections of the centers of the light inlets of the two first light-exiting holes on the circuit substrate are collinear with the orthographic projection of the center of the light-emitting element on the circuit substrate.

4. The light-emitting structure according to claim 1, wherein the two first light-exiting holes are respectively circular holes.

5. The light-emitting structure according to claim 1, wherein
the two first light-exiting holes are arranged at intervals, and the light-exiting part has a second light-exiting hole;
the second light-exiting hole is arranged between the two first light-exiting holes; and
the maximum dimension of the first light-exiting hole in the second direction is greater than a maximum dimension of the second light-exiting hole in the second direction.

6. The light-emitting structure according to claim 5, wherein
the second light-exiting hole is communicated with the two first light-exiting holes; and
orthographic projections of centers of light inlets of the two first light-exiting holes on the circuit substrate, an orthographic projection of a center of a light inlet of the second light-exiting hole on the circuit substrate, and an orthographic projection of a center of the light-emitting element on the circuit substrate are arranged in a collinear manner.

7. The light-emitting structure according to claim 5, wherein the two first light-exiting holes are respectively circular holes, and the second light-exiting hole is a strip-shaped hole.

8. The light-emitting structure according to claim 5, wherein
orthographic projections of light inlets of the two first light-exiting holes on the circuit substrate are respectively arranged on opposite sides of an orthographic projection of the light-emitting element on the circuit substrate; and
the orthographic projections of the light inlets of the two first light-exiting holes on the circuit substrate do not overlap with the orthographic projection of the light-emitting element on the circuit substrate.

9. The light-emitting structure according to claim 8, wherein the light-shielding body comprises a light-absorbing sub-body and a light-reflecting sub-body, the light-reflecting sub-body packages the outside of the light-transmitting body, the light-absorbing sub-body packages the outside of the light-reflecting sub-body, and a lateral side of the light-shielding body is flush with a lateral side of the circuit substrate.

10. The light-emitting structure according to claim 1, wherein the light-shielding body comprises a light-absorbing sub-body and a light-reflecting sub-body, the light-reflecting sub-body packages the outside of the light-transmitting body, the light-absorbing sub-body packages the outside of the light-reflecting sub-body, and a lateral side of the light-shielding body is flush with a lateral side of the circuit substrate.

11. A press key, comprising a keycap and the light-emitting structure according to claim 1; wherein
the keycap is provided with a light-emitting hole, the light-emitting hole is a strip-shaped hole, the light-emitting structure is arranged inside the keycap, the light-exiting part is arranged opposite to the light-emitting hole, and the two first light-exiting holes are arranged along a length direction of the strip-shaped hole.

12. The press key according to claim 11, wherein orthographic projections of centers of light inlets of the two first light-exiting holes on the circuit substrate are respectively arranged on opposite sides of an orthographic projection of a center of the light-emitting element on the circuit substrate.

13. The press key according to claim 12, wherein the orthographic projections of the centers of the light inlets of the two first light-exiting holes on the circuit substrate are collinear with the orthographic projection of the center of the light-emitting element on the circuit substrate.

14. The press key according to claim 11, wherein the two first light-exiting holes are respectively circular holes.

15. The press key according to claim 11, wherein
the two first light-exiting holes are arranged at intervals, and the light-exiting part has a second light-exiting hole;
the second light-exiting hole is arranged between the two first light-exiting holes; and
the maximum dimension of the first light-exiting hole in the second direction is greater than a maximum dimension of the second light-exiting hole in the second direction.

16. The press key according to claim 15, wherein
the second light-exiting hole is communicated with the two first light-exiting holes; and
orthographic projections of centers of light inlets of the two first light-exiting holes on the circuit substrate, an orthographic projection of a center of a light inlet of the second light-exiting hole on the circuit substrate, and an orthographic projection of a center of the light-emitting element on the circuit substrate are arranged in a collinear manner.

17. The press key according to claim 15, wherein the two first light-exiting holes are respectively circular holes, and the second light-exiting hole is a strip-shaped hole.

18. The press key according to claim 15, wherein
orthographic projections of light inlets of the two first light-exiting holes on the circuit substrate are respectively arranged on opposite sides of an orthographic projection of the light-emitting element on the circuit substrate; and
the orthographic projections of the light inlets of the two first light-exiting holes on the circuit substrate do not overlap with the orthographic projection of the light-emitting element on the circuit substrate.

19. The press key according to claim 18, wherein the light-shielding body comprises a light-absorbing sub-body and a light-reflecting sub-body, the light-reflecting sub-body packages the outside of the light-transmitting body, the light-absorbing sub-body packages the outside of the light-reflecting sub-body, and a lateral side of the light-shielding body is flush with a lateral side of the circuit substrate.

20. The press key according to claim 11, wherein the light-shielding body comprises a light-absorbing sub-body and a light-reflecting sub-body, the light-reflecting sub-body packages the outside of the light-transmitting body, the light-absorbing sub-body packages the outside of the light-reflecting sub-body, and a lateral side of the light-shielding body is flush with a lateral side of the circuit substrate.
